(19) United States
(12) Patent Application Publication
(10) Pub. No.: US 2020/0149168 A1
(43) Pub. Date: May 14, 2020

(54) FILM FORMING APPARATUS AND FILM FORMING METHOD

(71) Applicant: TOKYO ELECTRON LIMITED, Tokyo (JP)

(72) Inventor: Manabu HONMA, Oshu City (JP)

(21) Appl. No.: 16/677,043

(22) Filed: Nov. 7, 2019

(30) Foreign Application Priority Data
Nov. 12, 2018 (JP) 2018212423

(51) Int. Cl. C23C 16/52; C23C 16/458; C23C 16/455

(52) U.S. Cl. CPC C23C 16/52; C23C 16/45514; C23C 16/45519; C23C 16/4584

(57) ABSTRACT

A film forming apparatus includes: a stage configured to mount the substrate thereon; a raw material gas supply part that supplies a raw material gas to the substrate and adsorb the raw material gas onto the substrate, and includes divided supply portions configured to independently supply the raw material gas toward gas reception regions; raw material gas supply lines configured to supply the raw material gas in parallel toward the raw material gas supply part; concentration adjustment gas supply lines configured to supply a concentration adjustment gas for adjusting a concentration of the raw material gas toward the raw material gas supply part in a parallel relationship; and a reaction gas supply part configured to supply the reaction gas reacting with the raw material gas adsorbed onto the substrate to generate a reaction product constituting the thin film.

### CROSS-REFERENCE TO RELATED APPLICATION

This application is based upon and claims the benefit of priority from Japanese Patent Application No. 2018-212423, filed on Nov. 12, 2018, the entire contents of which are incorporated herein by reference.

### TECHNICAL FIELD

The present disclosure relates to a technique for forming a film by supplying a gas to a substrate.

### BACKGROUND

As one method for forming a thin film such as, for example, a silicon nitride film, on a semiconductor wafer (hereinafter referred to as a “wafer”) which is a substrate, there is known an ALD (Atomic Layer Deposition) method in which reaction products are stacked by alternately and repeatedly supplying a raw material gas and a reaction gas onto a front surface of the wafer. As a film forming apparatus for performing a film forming process using the ALD method, for example, as disclosed in Patent Document 1, there is available a configuration in which a rotary table for arranging a plurality of wafers side by side in a circumferential direction and revolving the wafers is provided inside a vacuum container. In this film forming apparatus, a raw material gas supply region and a reaction gas supply region spaced apart from each other in the rotational direction of the rotary table are formed. A film is formed on each of the wafers by alternately passing the wafers through the raw material gas supply region and the reaction gas supply region.

In a film forming apparatus for forming a film by supplying a raw material gas and a reaction gas to a revolving substrate, Patent Document 1 discloses a technique for setting the angle between gas injectors to be less than 180 degrees, and forming a region in which the reaction gas converted into plasma has a uniform concentration to make the film thickness uniform.

### PRIOR ART DOCUMENT

### Patent Documents

Patent Document 1: Japanese Laid-Open Patent Publication No. 2017-117943

### SUMMARY

According to one embodiment of the present disclosure, there is provided a film forming apparatus for forming a thin film by alternately supplying a raw material gas and a reaction gas to a substrate in a repetitive manner, including: a stage on which the substrate is mounted; a raw material gas supply part configured to supply the raw material gas to the substrate mounted on the stage and adsorb the raw material gas onto the substrate, the raw material gas supply part including a plurality of divided supply portions configured to independently supply the raw material gas toward a plurality of gas reception regions which are set by dividing a mounting surface of the stage on which the substrate is mounted; a plurality of raw material gas supply lines by which the plurality of divided supply portions are connected to a raw material gas source, the plurality of raw material gas supply lines configured to supply the raw material gas toward the raw material gas supply part in a parallel relationship with each other; a plurality of concentration adjustment gas supply lines by which the plurality of divided supply portions are connected to a concentration adjustment gas source, the plurality of concentration adjustment gas supply lines configured to supply a concentration adjustment gas for adjusting a concentration of the raw material gas toward the raw material gas supply part in a parallel relationship with each other, each of the plurality of concentration adjustment gas supply lines including supply/cutoff valves for selecting some of the plurality of divided supply portions to supply the concentration adjustment gas; and a reaction gas supply part configured to supply the reaction gas reacting with the raw material gas adsorbed onto the substrate to generate a reaction product constituting the thin film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view of a film forming apparatus according to a first embodiment of the present disclosure.

FIG. 2 is a plan view of the film forming apparatus.

FIG. 3 is a bottom plan view of a gas supply/exhaust unit.

FIG. 4 is a vertical sectional view of the gas supply/exhaust unit.

FIG. 5 is a block diagram showing an electrical configuration of the film forming apparatus.

FIG. 6 is a schematic diagram showing an example of a film thickness distribution when the concentration of a raw material gas is not adjusted.

FIG. 7 is an operation explanation diagram related to the adjustment of the concentration of a DCS gas.

FIG. 8 is a bottom plan view of a gas supply/exhaust unit according to another example.

FIG. 9 is a bottom plan view of a gas supply/exhaust unit according to another example.

FIG. 10 is a vertical sectional view of the gas supply/exhaust unit.

FIG. 11 is a first operation explanation diagram of a film forming apparatus according to a second embodiment.

FIG. 12 is a second operation explanation diagram of the film forming apparatus.

FIG. 13 is a third operation explanation diagram of the film forming apparatus.

FIG. 14 is a fourth operation explanation diagram of the film forming apparatus.

FIG. 15 is a fifth operation explanation diagram of the film forming apparatus.

FIG. 16 is a characteristic diagram showing a film thickness distribution in Example 1.

FIG. 17 is a characteristic diagram showing a film thickness distribution in Example 2.

FIG. 18 is a characteristic diagram showing a variation in film thickness in Examples 1 and 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

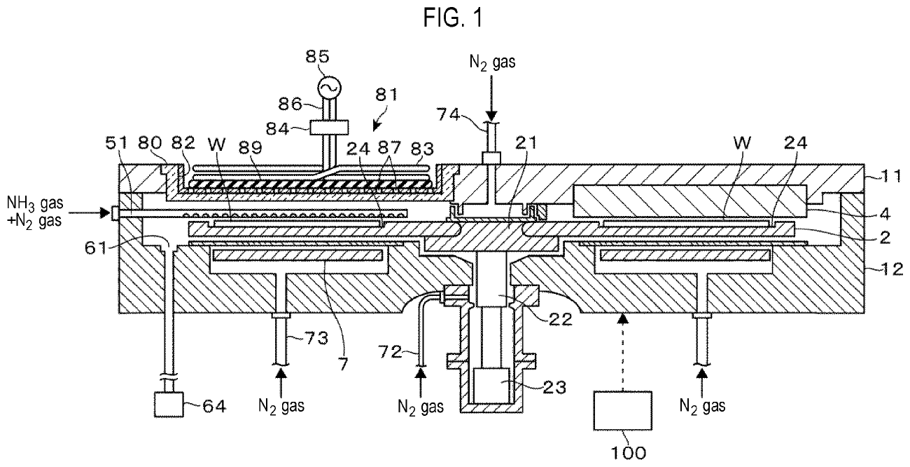

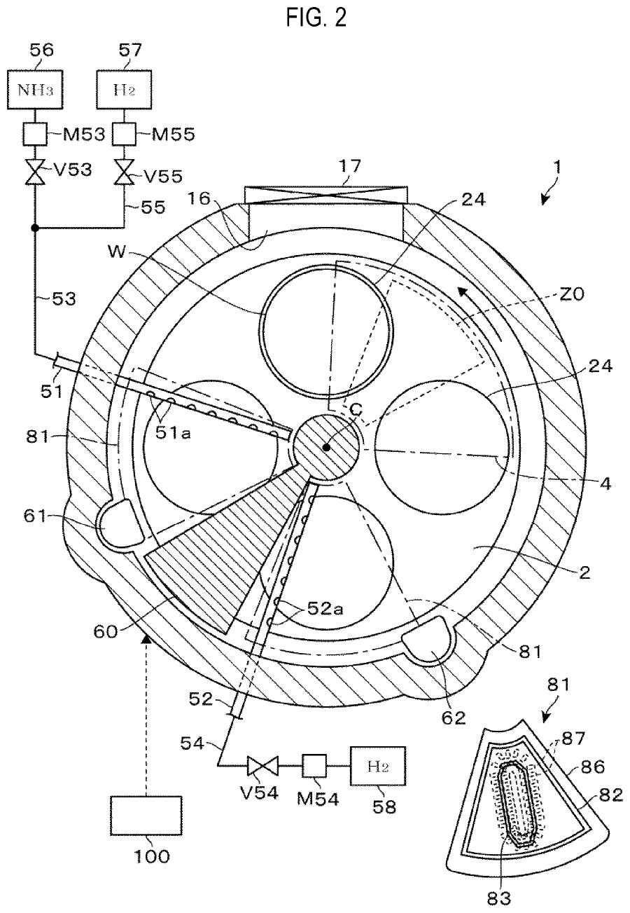

A film forming apparatus according to a first embodiment will be described. As shown in FIGS. 1 and 2, the film forming apparatus includes a vacuum container 1 having a substantially circular planar shape, and a rotary table 2 as a stage provided inside the vacuum container 1 and made of, for example, quartz. The rotary table 2 has a rotation center C coinciding with the center of the vacuum container 1 and revolves wafers W around the rotation center C. The vacuum container 1 includes a top plate 11 and a container main body 12. The top plate 11 is configured to be detachable from the container main body 12. A separation gas supply pipe 74 for supplying a nitrogen (N₂) gas as a separation gas is connected to the central portion of an upper surface of the top plate 11 in order to suppress different processing gases from being mixed with each other in an inner central portion of the vacuum container 1.

The rotary table 2 is fixed to a substantially cylindrical core portion 21 at the center thereof. The rotary table 2 is configured to be rotatable about a vertical axis (in this example, counterclockwise when viewed from above) coinciding with the rotation center C in FIG. 2, by a rotation shaft 22 that is connected to a lower surface of the core 21 and extends in the vertical direction. Reference numeral 23 in FIG. 1 denotes a rotation mechanism that rotates the rotation shaft 22 about a vertical axis. An N₂ gas as a purge gas is supplied from a purge gas supply pipe 72 around the rotation shaft 22 and the rotation mechanism 23.

Four circular recesses 24 on which wafers W are respectively mounted are provided in an upper surface of the rotary table 2 along the circumferential direction (rotational direction). In addition, a heater 7 as a temperature adjustment part for adjusting a temperature of the rotary table 2 and heating the wafers W mounted on the rotary table 2 to, for example, 450 degrees C., is provided concentrically in the bottom of the vacuum container 1. Reference numeral 73 in FIG. 1 denotes a purge gas supply pipe for supplying an N₂ gas as a purge gas into a region where the heater 7 is provided.

As shown in FIG. 2, a transfer port 16 for loading and unloading the wafer W therethrough is formed in a sidewall of the vacuum container 1. The transfer port 16 is configured to be opened and closed by a gate valve 17. Below the rotary table 2 in a region facing the transfer port 16 inside the vacuum container 1, there are provided lifting pins (not shown) for pushing up the wafer W mounted on the rotary table 2 from below. When the wafer W is loaded and unloaded, the wafer W is delivered between the outside of the vacuum container 1 and the inside of the recess 24 via the transfer port 16 in cooperation between a substrate transfer mechanism (not shown) provided outside the film forming apparatus and the lifting pins.

As shown in FIG. 2, a gas supply/exhaust unit 4, a reaction gas nozzle 51 and a modification gas nozzle 52 are provided above the rotary table 2. The gas supply/exhaust unit 4 supplies a DCS (dichlorosilane) gas as a raw material gas toward the wafer W that is being revolved by the rotary table 2. The reaction gas nozzle 51 supplies a mixed gas of an NH₃ gas and a H₂ gas, which are reaction gases, that reacts with the DCS gas to form a thin film on the wafer W. The modification gas nozzle 52 supplies a H₂ gas which is a modification gas. The rotational direction of the rotary table 2 (the counterclockwise direction in this example) is assumed as a front side and a direction opposite to the rotational direction (the clockwise direction in this example) is assumed as a rear side. Then, the gas supply/exhaust unit 4 and the nozzles 51 and 52 are provided in the named order toward the front side along the rotational direction. That is to say, the gas supply/exhaust unit 4 and the reaction gas nozzle 51 are spaced apart from each other in the direction of revolution of the wafer W mounted on the stage. In the following description, the revolution direction of the wafer W will be referred to as a front side of the wafer W, and a direction opposite to the revolution direction of the wafer W will be referred to as a rear side of the wafer W. The reaction gas nozzle 51 corresponds to a reaction gas supply part.

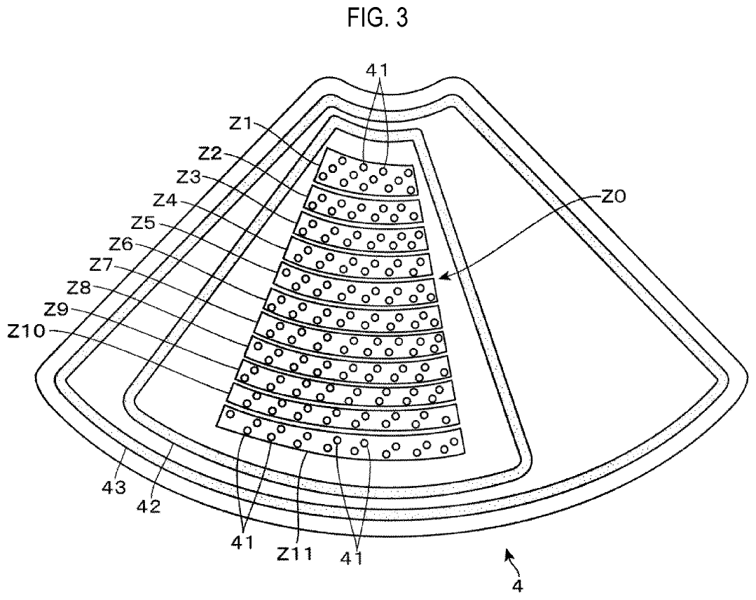

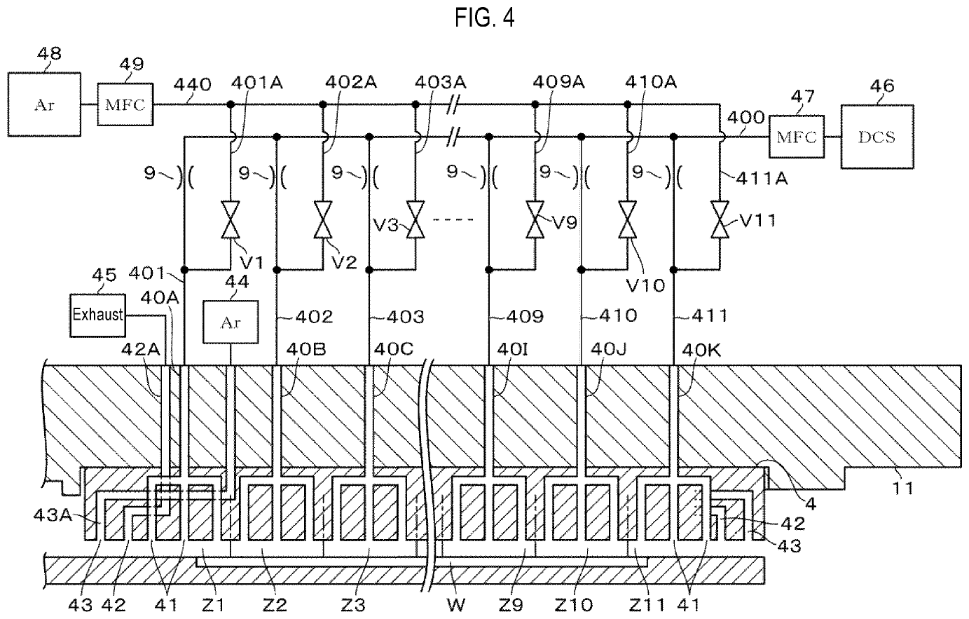

As shown in FIGS. 3 and 4, the gas supply/exhaust unit 4 is made of, for example, an aluminum member having a fan-like planar shape. Gas discharge ports 41, an exhaust port 42 and a purge gas discharge port 43 are formed in a lower surface of the gas supply/exhaust unit 4. The gas supply/exhaust unit 4 is arranged in such an orientation that when viewed from a mounting surface of the wafer W, the fan shape expands from an inner peripheral side toward an outer peripheral side of the revolution center of the mounting surface. In FIG. 3, in order to facilitate discrimination, the exhaust port 42 and the purge gas discharge port 43 are indicated by a large number of dots. A large number of gas discharge ports 41 are arranged in a fan-shaped region Z0 that expands from the inner peripheral side to the outer peripheral side of the rotation center of the rotary table 2 inward of the peripheral edge portion of the lower surface of the gas supply/exhaust unit 4. The gas discharge ports 41 discharges the DCS gas downward in the form of a shower while the rotary table 2 is rotating during a film forming process, and supplies the DCS gas onto the entire surface of the wafer W. The fan-shaped region Z0 in which the large number of gas discharge ports 41 are arranged corresponds to a raw material gas supply part.

With respect to the rotary table 2 that passes below the fan-shaped region Z0, a plurality of “gas reception regions” is divided in the radial direction and set to extend from the inner peripheral side toward the outer peripheral side of the revolution center of the mounting surface of the wafer W. In the meantime, eleven divided supply portions Z1 to Z11 for supplying the DCS gas independently of one another toward the gas reception regions are set in the fan-shaped region Z0. That is to say, the divided supply portions Z1 to Z11 are also divided in the radial direction from the inner peripheral side to the outer peripheral side of the revolution center of the mounting surface of the wafer W. As shown in FIG. 4, the gas supply/exhaust unit 4 is provided with mutually-separated gas flow paths 40A to 40K so that the DCS gas can be supplied independently from the gas discharge ports 41 of the respective divided supply portions Z1 to Z11.

Upstream sides of the gas flow paths 40A to 40K are connected to one ends of DCS gas supply lines 401 to 411 for supplying the DCS gas, respectively. The other ends of the DCS gas supply lines 401 to 411 are connected to one end of a common DCS gas supply pipe 400. A mass flow controller (MFC) 47 is provided in the DCS gas supply pipe 400. The other end of the DCS gas supply pipe 400 is connected to the DCS gas source 46. The DCS gas supply lines 401 to 411 correspond to raw material gas supply lines of this embodiment, and the DCS gas source 46 corresponds to a raw material gas source.

Therefore, the divided supply portions Z1 to Z11 are connected to the DCS gas source 46 in a parallel relationship with each other via the respective DCS gas supply lines 401 to 411. The DCS gas supply lines 401 to 411 are provided with orifices as flow rate ratio adjustment parts for branching the gas supplied from the DCS gas source 46 to the divided supply portions Z1 to Z11 so as to have a predetermined flow rate ratio.

Furthermore, one ends of Ar gas supply lines 401A to 411A for supplying an argon gas (Ar gas) as a concentration adjustment gas therethrough are connected to the DCS gas supply lines 401 to 411 at the downstream side of the orifices 9 (at the side of the divided supply portions Z1 to Z11), respectively. The other end of each of the Ar gas supply lines 401A to 411A is connected to one end of an Ar gas supply pipe 440. The other end of the Ar gas supply pipe 440 is connected to an Ar gas source 48. The Ar gas supply lines 401A to 411A correspond to concentration adjustment gas supply lines of this embodiment, and the Ar gas source 48 corresponds to a concentration adjustment gas source.

Accordingly, the divided supply portions Z1 to Z11 are connected to the Ar gas source 48 in a parallel relationship with each other via the respective Ar gas supply lines 401A to 411A. The respective Ar gas supply lines 401A to 411A are provided with Ar gas valves V1 to V11 which are supply/cutoff valves. An MFC 49 is provided in the Ar gas supply pipe 440. In this embodiment, when an opening signal is received, each of the Ar gas valves V1 to V11 is opened to supply an Ar gas. When a closing signal is received, each of the Ar gas valves V1 to V11 is closed to stop the supply of the Ar gas. In the following description, the opened state and the closed state of the Ar gas valves V1 to V11 will be also referred to as “on” and “off”, respectively.

Next, the exhaust port 42 and the purge gas discharge port 43 formed in the lower surface of the gas supply/exhaust unit 4 will be described. The exhaust port 42 and the purge gas discharge port 43 are annularly formed in a peripheral edge portion of the lower surface of the gas supply/exhaust unit 4. The purge gas discharge port 43 is located outside the exhaust port 42 provided so as to surround the fan-shaped region Z0 (see FIG. 3).

Reference numerals 42A and 43A in FIG. 4 denote gas flow paths that are partitioned from each other and provided in the gas supply/exhaust unit 4. The gas flow paths 42A and 43A are also partitioned from the above-described DCS gas flow paths 40A to 40K. An upstream end of the gas flow path 42A is connected to the exhaust port 42, and a downstream end of the gas flow path 42A is connected to the exhaust device 45. The exhaust device 45 can exhaust a gas from the exhaust port 42. Furthermore, a downstream end of the gas flow path 43A is connected to the purge gas discharge port 43, and an upstream end of the gas flow path 43A is connected to a source 44 of an Ar gas as a purge gas.

During the film forming process, the discharge of the DCS gas from the gas discharge ports 41, the exhaust of the gas from the exhaust port 42 and the discharge of the purge gas from the purge gas discharge port 43 are performed in parallel. Thus, the DCS gas and the purge gas discharged toward the rotary table 2 flow over the upper surface of the rotary table 2 and then travel toward the exhaust port 42. The DCS gas and the purge gas are exhausted from the exhaust port 42. As the purge gas is discharged and exhausted in this way, an atmosphere below the fan-shaped region Z0 is separated from an external atmosphere. Thus, it is possible to supply the DCS gas toward only a region facing the fan-shaped region Z0 in the rotary table 2.

Returning to FIG. 2, the reaction gas nozzle 51 and the modification gas nozzle 52 are substantially identical in configuration with each other except that the gases discharged therefrom are different. The reaction gas nozzle 51 and the modification gas nozzle 52 are configured in, for example, an elongated bar shape whose front end is closed. Each of the reaction gas nozzle 51 and the modification gas nozzle 52 extends horizontally from the sidewall of the vacuum container 1 toward the center of the rotary table 2. Each of the reaction gas nozzle 51 and the modification gas nozzle 52 is provided so as to intersect with a region (passage region) through which the wafers W on the rotary table 2 pass. Gas discharge holes 51a and 52a for discharging gases therethrough are respectively formed in front lateral surfaces of the reaction gas nozzle 51 and the modification gas nozzle 52 in the rotational direction of the rotary table 2 so that they are arranged side by side along a length direction.

One end of a reaction gas supply pipe 53 is connected to a base end of the reaction gas nozzle 51, and the other end of the reaction gas supply pipe 53 is connected to an NH₃ gas source 56 filled with an ammonia (NH₃) gas. Furthermore, one end of a hydrogen (H₂) gas supply pipe 55 is connected to the reaction gas supply pipe 53. A H₂ gas source 57 is connected to the other end of the H₂ gas supply pipe 55. One end of a modification gas supply pipe 54 is connected to a base end of the modification gas nozzle 52, and the other end of the modification gas supply pipe 54 is connected to an H₂ gas source 58 filled with a H₂ gas. Reference numerals V53, V54 and V55 in FIG. 2 denote valves provided in the reaction gas supply pipe 53, the modification gas supply pipe 54 and the H₂ gas supply pipe 55, respectively. Reference numerals M53, M54 and M55 denote flow rate adjustment parts provided in the reaction gas supply pipe 53, the modification gas supply pipe 54 and the H₂ gas supply pipe 55, respectively.

Furthermore, a plasma generation part 81 is provided above a region of the top plate 11 extending forward from a position of each of the reaction gas nozzle 51 and the modification gas nozzle 52. As shown in FIGS. 1 and 2, for example, the plasma generation part 81 has a structure in which an antenna 83 configured by winding a metal wire in a coil shape is accommodated in a casing 80 made of, for example, quartz. The antenna 83 is connected to a high-frequency power source 85 having a frequency of, for example, 13.56 MHz, and an output power of, for example, 5,000 W, through a connection electrode 86 provided with a matcher 84. Reference numeral 82 in FIGS. 1 and 2 denotes a Faraday shield that blocks an electric field generated from the antenna 83, and reference numeral 87 denotes a slit for allowing a magnetic field generated from the antenna 83 to reach the wafer W. Reference numeral 89 denotes an insulating plate provided between the Faraday shield 82 and the antenna 83.

In a processing space above the rotary table 2, a region below the gas supply/exhaust unit 4 corresponds to an adsorption region where the DCS gas is adsorbed, and a region below the reaction gas nozzle 51 corresponds to a reaction region where the DCS gas is nitrided. In addition, a region below the plasma generation part 81 provided in a corresponding relationship with the modification gas nozzle 52 corresponds to a modification region where a SiN film is modified by plasma.

A region between the back side of the modification gas nozzle 52 and at the front side of the plasma generation part 81 corresponding to the reaction gas nozzle 51 in the rotational direction of the rotary table 2, corresponds to a separation region 60. A ceiling surface of the separation region 60 is set to be lower than a ceiling surface on which the plasma generation part 81 is provided. The separation region 60 is provided to prevent the NH₃ gas supplied to the back side of the separation region 60 in the rotational direction of the rotary table 2 from being mixed with and diluted by the H₂ gas supplied to the front side of the separation region 60 in the rotational direction of the rotary table 2. The gas supply/exhaust unit 4 can also form a curtain of a separation gas so as to intersect the passage region of the wafer W. Thus, it can be said that the gas supplied from the reaction gas nozzle 51 is prevented from being diluted by the gas supplied from the modification gas nozzle 52.

Furthermore, as shown in FIG. 2, exhaust ports 61, 62 are respectively formed outside the rotary table 2 at positions facing the front side of the reaction gas nozzle 51 and the front side of the modification gas nozzle 52 when viewed in the rotational direction of the rotary table 2. Reference numeral 64 in FIG. 1 denotes an exhaust device. The exhaust device 64 is configured by a vacuum pump or the like and is connected to the exhaust ports 61 and 62 through exhaust pipes.

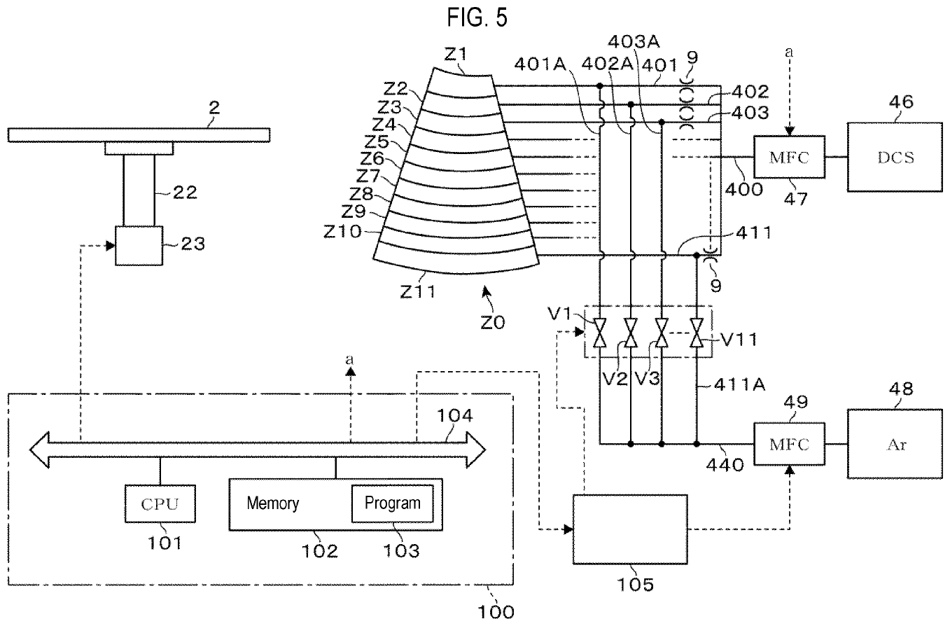

As shown in FIGS. 1 and 2, the film forming apparatus is provided with a controller 100 including a computer for controlling the operation of the entire apparatus. Referring also to FIG. 5, the controller 100 includes a CPU 101 and a memory 102. A program (film forming recipe) 103 for executing a group of steps related to a film forming process for the wafer W described later is stored in the memory 102. Reference numeral 104 in FIG. 5 denotes a bus. Furthermore, the controller 100 outputs control signals for controlling the rotation of the rotary table 2, the supply/cutoff of each of the DCS gas, the reaction gas and the modification gas, the exhaust of the gas from the vacuum container 1, and the like.

Also connected to the controller 100 is an external sequencer 105 which is a controller for controlling the opening and closing of the Ar gas valves V1 to V11 and the adjustment of a flow rate of the Ar gas by an MFC 49. The external sequencer 105 is configured by, for example, a computer and is configured to store a program for opening and closing each of the Ar gas valves V1 to V11. For example, when a signal for starting the film forming process is inputted from the controller 100, a control signal for opening or closing the Ar gas valves V1 to V11 is outputted to the Ar gas valves V1 to V11 in accordance with the film forming recipe to perform the supply/cutoff of the Ar gas as indicated in the operation to be described later.

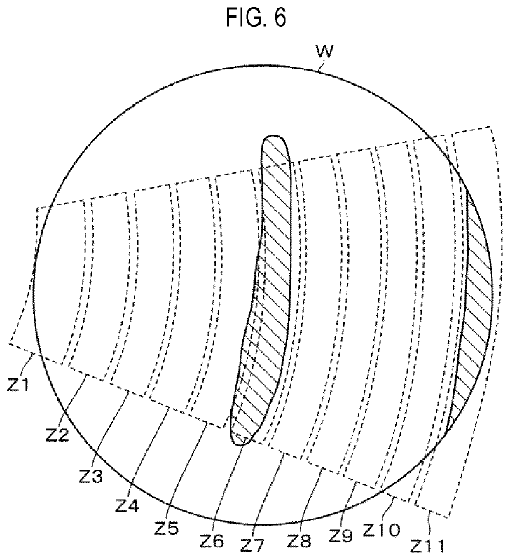

When performing the film forming process using the film forming apparatus having the above-described configuration, a thickness of a film formed on the wafer W may become uneven by turbulence of an air flow due to the shape of the recesses 24 for accommodating the wafers W, the non-uniformity of plasma, or the like. FIG. 6 is a schematic view showing an example of a film thickness distribution when a film forming process is performed with the film forming apparatus according to the present disclosure by supplying the DCS gas, the concentration of which is not adjusted by the Ar gas, to the divided supply portions Z1 to Z11. In the wafer W, the film thickness of portions passing through predetermined regions, for example, a gas reception region corresponding to the divided supply portion Z6 near the center of the wafer W and a gas reception region corresponding to the divided supply portion Z11 at the outer peripheral side of the rotary table 2 in the example shown in FIG. 6, becomes large.

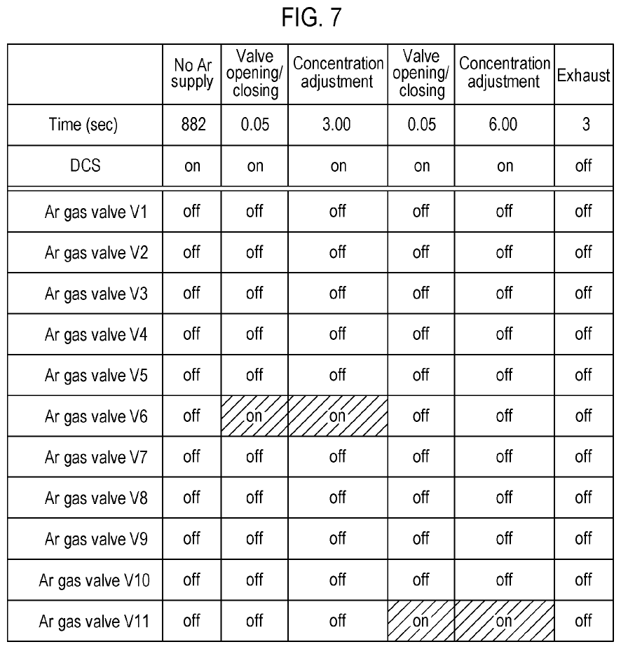

Therefore, in the film forming apparatus and the film forming method according to the present disclosure, the film thickness distribution of the film formed on the wafer W as shown in FIG. 6 is grasped in advance, and the film forming process is performed so as to suppress the formation of a thick portion. An opening/closing sequence shown in FIG. 7 is created in a corresponding relationship with the film thickness distribution shown in FIG. 6. That is to say, according to the opening/closing sequence, the Ar gas valves V1 to V11 are opened or closed so as to suppress an increase in the film thickness of the thin film of the portions passing through the gas reception regions corresponding to the divided supply portion Z6 and the divided supply portion Z11, at which the film thickness becomes large as in the example shown in FIG. 6. The opening/closing sequence of the Ar gas valves V1 to V11 is stored in the external sequencer 105. The item of DCS described in FIG. 7 indicates the supply/cutoff of the DCS gas (ON/OFF of each of the Ar gas valve V1 to V11). The supply/cutoff of the DCS gas is controlled by the film forming recipe of the controller 100 and is performed independently of the control by the external sequencer 105. However, for the sake of convenience in description, the supply/cutoff of the DCS gas is also shown in FIG. 7.

Next, the operation of the film forming apparatus of the present disclosure based on the opening/closing sequence of FIG. 7 will be described. First, the gate valve 17 is opened, and the wafers W are delivered to the respective recesses 24 of the rotary table 2 in cooperation between the lifting pins and the substrate transfer mechanism while intermittently rotating the rotary table 2. Subsequently, the gate valve 17 is closed to make the inside of the vacuum container 1 airtight. The wafer W mounted in each recess 24 is heated to, for example, 500 degrees C., by the heater 7. In addition, the inside of the vacuum container 1 is brought into a vacuum atmosphere having a pressure of, for example, 2 Torr (266.6 Pa) by exhausting the gases from the exhaust ports 61 and 62. The rotary table 2 is rotated clockwise at a rotational speed ranging from 1 to 300 rpm, for example, 10 rpm.

Subsequently, a NH₃ gas and a H₂ gas are supplied from the reaction gas nozzle 51, and an H₂ gas is supplied from the modification gas nozzle 52. While supplying each gas in this way, a high frequency power is supplied from each plasma generation part 81 to form each gas into a plasma. In the gas supply/exhaust unit 4, a DCS gas is supplied from all the gas discharge ports 41. Furthermore, an Ar gas is discharged from the purge gas discharge port 43, and gases are exhausted from the exhaust port 42.

For example, when the rotary table 2 begins to rotate, the controller 100 outputs a trigger signal for starting the opening/closing sequence of the Ar gas valves V1 to V11 to the external sequencer 105. As shown in FIG. 7, in the opening/closing sequence of the Ar gas valves V1 to V11, all the Ar gas valves V1 to V11 are initially set to OFF so that the supply of the Ar gas to all the divided supply portions Z1 to Z11 is stopped. As a result, according to a pressure loss obtained by adjusting the orifices 9 provided in the respective DCS gas supply lines 401 to 411, the DCS gas is sorted with respect to the divided supply portions Z1 to Z11 at a preset flow rate ratio. In the example of the opening/closing sequence shown in FIG. 7, the film forming process is performed for 882 seconds in this state.

When the wafer W is positioned below the gas supply/exhaust unit 4 with the rotation of the rotary table 2, the DCS gas is supplied toward and adsorbed onto the front surface of the wafer W. As the wafer W arrives below the reaction gas nozzle 51 with the continuous rotation of the rotary table 2, the DCS adsorbed onto the wafer W reacts with the NH₃ to generate SiN as a reaction product. Furthermore, Cl (chlorine) remaining on the wafer W is removed by active species of hydrogen generated by forming the H₂ gas supplied to the region into plasma. As the wafer W arrives below the modification gas nozzle 52 by the continuous rotation of the rotary table 2, Cl remaining on the wafer W is removed by the active species of hydrogen.

Thus, as the rotary table 2 continues to rotate as described above, the wafer W sequentially passes below the gas supply/exhaust unit 4, the reaction gas nozzle 51 and the modification gas nozzle 52 a plurality of times in a repetitive manner, whereby SiN is deposited on the front surface of the wafer W to form a thin film of SiN (SiN film) and the modification of the SiN film proceeds.

When a preset time (882 seconds in this example) elapses from the start of supply of the DCS gas, a signal for opening the Ar gas valve V6 for 3 seconds is outputted while continuously supplying the DCS gas. In this example, a time from when the Ar gas valve V6 receives the opening signal to when the Ar gas valve V6 is fully opened is 0.05 seconds. Therefore, a time from when the Ar gas valve V6 receives the opening signal to when the Ar gas valve V6 receives a closing signal is set to 3.05 seconds. As a result, the DCS gas supplied from the divided supply portion Z6 toward the mounting surface for the wafer W is diluted (concentration-adjusted) with the Ar gas for 3 seconds.

Subsequently, the external sequencer 105 outputs a signal for turning off the Ar gas valve V6 and outputs a signal for turning on the Ar gas valve V11 for 6 seconds (a time from when the Ar gas valve V11 receives the turning-on signal to when the Ar gas valve V11 receives a turning-off signal is 6.05 seconds). Thus, the DCS gas supplied from the divided supply portion Z11 toward the mounting surface for the wafer W is diluted (concentration-adjusted) with the Ar gas for 6 seconds. Thereafter, the supply of the DCS gas is stopped and the external sequencer 105 outputs the turning-off signal for the Ar gas valve V11. As a result, the supply of all of the DCS gas, the reaction gas, the modification gas and the Ar gas for concentration adjustment is ceased and the inside of the vacuum container 10 is exhausted.

A film forming mechanism when a gas is supplied to the wafer W will now be described. When the DCS gas is supplied to the wafer W, the DCS gas is repeatedly adsorbed onto and desorbed from the wafer W. The DCS gas remaining after adsorption to the wafer W reacts with a subsequent reaction gas to form a film on the wafer W. By diluting the DCS gas with the Ar gas when supplying the DCS gas to the wafer W, the amount of adsorption of the DCS gas onto the front surface of the wafer W is reduced. Therefore, when supplying the DCS gas to the entire front surface of the wafer W, the concentration is adjusted by locally mixing the Ar gas with the DCS gas, whereby the film thickness is reduced in a region where the concentration-adjusted DCS gas is blown.

Therefore, by performing the film forming process according to the film forming recipe while executing the opening/closing sequence shown in FIG. 7, the concentration-adjusted DCS gas is sequentially supplied to the gas reception regions corresponding to the divided supply portions Z6 and Z11. As a result, it is possible to suppress an increase in the film thickness in the regions shown in FIG. 6.

As described with reference to FIG. 6, when the film forming process is performed without supplying the Ar gas to the divided supply portions Z1 to Z11, the thickness of the SiN film at the positions at which the wafer W passes through the gas reception regions facing the divided supply portions Z6 and Z11 tends to increase. Therefore, by adjusting the concentration of the DCS gas supplied from the divided supply portions Z6 and Z11 through the dilution for a predetermined period of time, it is possible to suppress a partial increase in the film thickness and to enhance the in-plane uniformity of the thickness of the SiN film.

According to the above-described embodiment, the film forming apparatus supplies the DCS gas (raw material gas) and the NH₃ gas (reaction gas) to the wafer W in a repetitive manner to generate a thin film. In this case, there is provided the gas supply/exhaust unit 4 including the divided supply portions Z1 to Z11 for independently supplying the DCS gas toward the gas reception regions set by dividing the mounting surface of the wafer W. In addition, the divided supply portions Z1 to Z11 are coupled to the DCS gas source 46 which supplies the DCS gas to the gas supply/exhaust unit 4, in a parallel relationship with each other by the DCS gas supply lines 401 to 411. The orifices 9 for sorting and supplying the DCS gas at a preset flow rate ratio are provided in the respective DCS gas supply lines 401 to 411. Furthermore, the divided supply portions Z1 to Z11 are coupled to the Ar gas source 48 which supplies the Ar gas to the gas supply/exhaust unit 4, in a parallel relationship with each other by the Ar gas supply lines 401A to 411A. The Ar gas valves V1 to V11 are provided in the respective Ar gas supply lines 401A to 411A. As a result, the DCS gas can be supplied to each of the divided supply portions Z1 to Z11 in the state where the concentration of the DCS gas is adjusted by the supply and cutoff of the Ar gas. Therefore, the amount of the DCS gas adsorbed onto the wafer W can be adjusted for each of the regions facing the divided supply portions Z1 to Z11, thus adjusting the film thickness of the film formed in the plane of the wafer W.

In the present embodiment, the film thickness of the film formed in the plane of the wafer W is adjusted only by switching the supply and cutoff of the Ar gas supplied to the divided supply portions Z1 to Z11. This eliminates a need to employ a complicated structure such as providing a flow rate adjustment part in a line for supplying a gas to each of the divided supply portions Z1 to Z11, which makes it possible to achieve a simplified configuration.

In addition, the present inventors have found that when adjusting the concentration of the raw material gas, the influence of a variation in the thickness of the SiN film on a unit flow rate variation is larger when increasing or decreasing a flow rate of the Ar gas as an inert gas than when increasing or decreasing a flow rate of the DCS gas. Since the SiN film is formed through a chemical reaction after physical adsorption, it is considered that a reaction time is rate-limited, and the sensitivity of the adsorption amount of DCS to the variation in film thickness of the SiN film is relatively small even if the supply amount of the DCS gas is varied. On the other hand, an increase or decrease in the mixing amount of Ar having a relatively great atomic weight directly affects the inhibition of physical adsorption of DCS onto the wafer W. It is presumed that the influence of the increase or decrease in the mixing amount of Ar on the variation in film thickness of the SiN film is large. Accordingly, it can be said that the gas supply/exhaust unit 4 of this embodiment for supplying or cutting off the Ar gas from the Ar gas supply lines 401A to 411A toward the respective DCS gas supply lines 401 to 411 has a configuration capable of easily adjusting the thickness of the SiN film passing through the respective gas reception regions.

In the present embodiment, the supply time of the Ar gas supplied to the predetermined divided supply portions Z1 to Z11 (the on/off time of the Ar gas valves V1 to V11) with respect to the total time during which the DCS gas is supplied is adjusted. Thus, for example, as compared with the case where MFCs are provided in the respective DCS gas supply lines 401 to 411 to separately adjust the supply flow rates of the DCS gas, it is possible to easily adjust the film thickness of the wafer W passing through the gas reception regions that face the divided supply portions Z1 to Z11. Alternatively, the supply of the DCS gas may be performed only by the pressure loss in pipes or the like, instead of providing the orifices 9 in the respective DCS gas supply lines 401 to 411.

The opening/closing sequence shown in FIG. 7 may be changed, and a sequence of performing the concentration adjustment of the DCS gas may be changed. For example, the Ar gas may be first supplied to the predetermined divided supply portions Z6 and Z11 while supplying the DCS gas. Subsequently, the Ar gas supply may be stopped to perform the film forming process using the DCS gas alone. Alternatively, the film forming process may be performed while continuously supplying the Ar gas from the start to the end of the supply of DCS gas.

In the above-described embodiment, the divided supply portions Z1 to Z11 are divided into 11 sections. However, the film thickness distribution control which utilizes the concentration adjustment of the DCS gas by the supply and cutoff of the Ar gas may be applied to any film forming apparatus in which two or more divided supply portions are provided.

Furthermore, the technique according to the present disclosure may be applied to a single-wafer type film forming apparatus in which a film is formed by supplying a gas toward one wafer W mounted on a stage. In some embodiments, the technique of the present disclosure may be applied to a film forming apparatus that supplies a raw material gas and a reaction gas toward a wafer movement region in which the wafer W linearly moves, instead of supplying the DCS gas toward the wafer W revolving around the vertical axis.

In addition, for example, the divided supply portions Z1 to Z11 in the fan-shaped region Z0 shown in FIGS. 3 and 4 may be further divided into a plurality of sets (e.g., a first set of divided regions Z1 to Z5 and a second set of divided regions Z6 to Z11). In this case, one set of the DCS gas source 46, the DCS gas supply lines 401 to 405, the Ar gas source 48 and the Ar gas supply lines 401A to 405A may be provided for the first set of the divided regions. The other set of the DCS gas source 46, the DCS gas supply lines 406 to 411, the Ar gas source 48 and the Ar gas supply lines 406A to 411A may be provided for the second set of the divided regions.

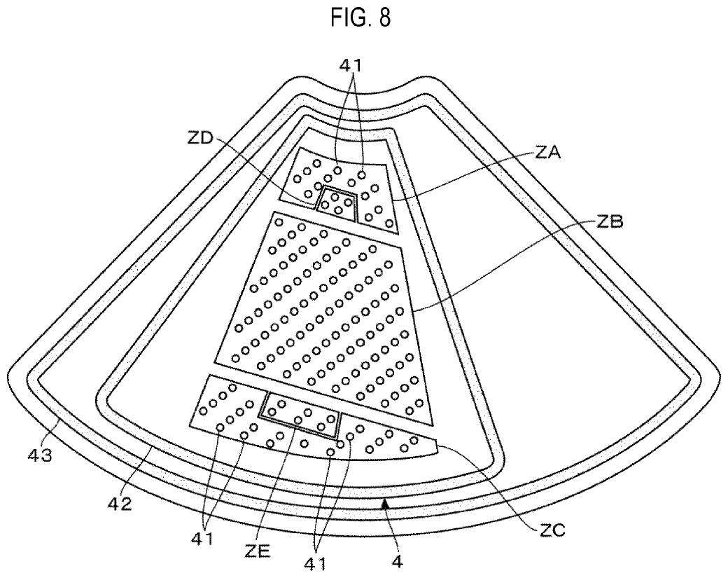

FIG. 8 shows another example of the gas supply/exhaust unit 4. In this example, among five divided supply portions ZA to ZE, divided supply portions ZD and ZE are respectively sandwiched in an island shape between other divided supply portions ZA to ZC arranged at positions adjacent to each other along a radial direction. As shown in Examples described later, by forming the divided supply portions ZD and ZE in an island shape, the variation in film thickness can be adjusted along the revolution direction of the wafers W.

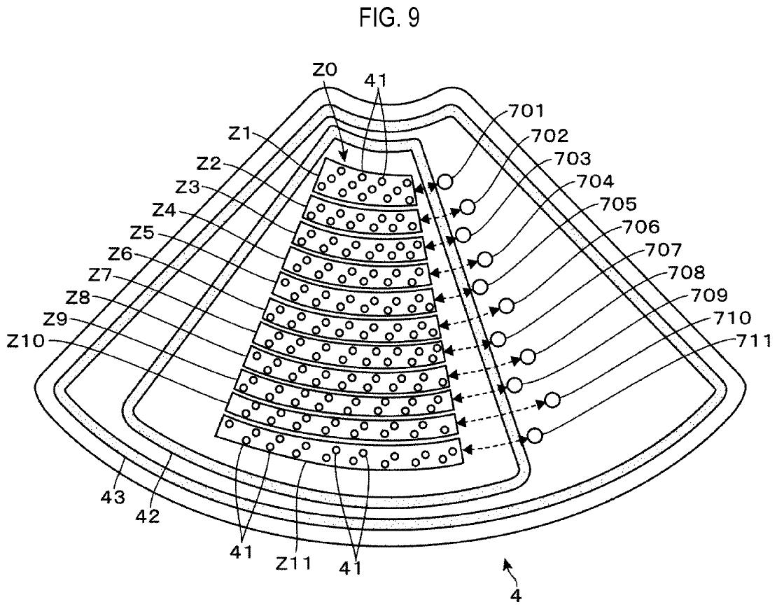

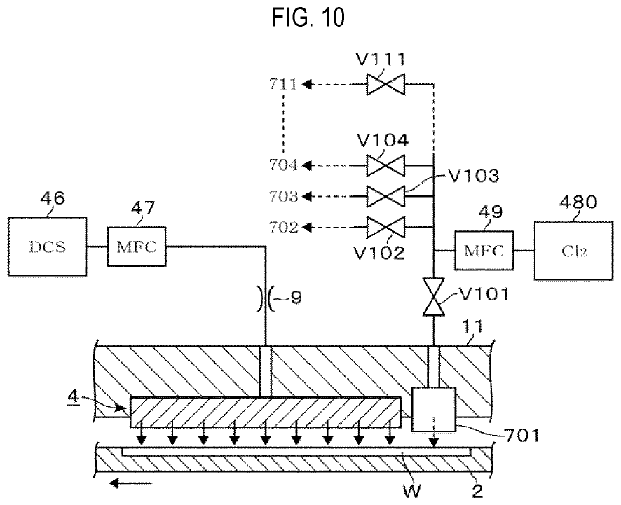

FIGS. 9 and 10 show an example in which the thickness distribution of the SiN film is adjusted using a reaction inhibition gas in addition to the Ar gas for concentration adjustment.

The reaction inhibition gas is a gas that competes with the DSC gas and adsorbs onto the wafer W but does not generate a reaction product even when the NH₃ gas is supplied. An example of the reaction inhibition gas may include a Cl gas.

The film forming apparatus shown in FIGS. 9 and 10 includes a plurality of gas supply pads 701 to 711 which are reaction inhibition gas supply parts for supplying the Cl gas. In the example shown in FIGS. 9 and 10, when viewed from the fan-shaped region Z0, the gas supply pads 701 to 711 are provided at the upstream side in the rotational direction of the rotary table 2 so as to correspond to the respective divided supply portions Z1 to Z11. As a result, the Cl gas, which is a reaction inhibition gas, can be supplied to different positions in the radial direction of the rotary table 2 at a region near positions receiving the DCS gas supplied from the gas supply/exhaust unit 4 with the revolution of the wafers W. Arrows in FIG. 9 indicate combinations of the divided supply portions Z1 to Z11 and the gas supply pads 701 to 711 corresponding to the divided supply portions Z1 to Z11. Furthermore, valves V101 to V111 are provided in Cl gas supply lines 401B to 411B through which the Cl gas supplied from a Cl gas source 480 is supplied to the gas supply pads 701 to 711, respectively. Thus, it is possible to individually switch the supply and cutoff of the Cl gas from the gas supply pads 701 to 711. Furthermore, a film forming process is performed in the same manner as the above-described embodiment. The valves V101 to V111 are opened and closed in conformity with the opening and closing timings of the Ar gas valves V1 to V11, such that the Cl gas is supplied from the respective gas supply pads 701 to 711.

When the Cl gas is supplied to the wafer W, the Cl gas is adsorbed onto the wafer prior to the DCS gas. As a result, the adsorption of a silicon-based gas such as a DCS gas or the like is inhibited at the site where the Cl gas adheres. Furthermore, the Cl gas does not react with a reaction gas, i.e., a NH₃ gas in this example, to form a thin film. Therefore, the thickness of the SiN film can be reduced by adjusting the amount of adsorption of the DCS gas so as to be locally reduced in the region where the Cl gas is adsorbed.

Some of the gas supply pads 701 to 711 may be constituted as a raw material gas preliminary supply part that supplies the DCS gas instead of supplying the Cl gas. As a result, it is possible to suppress an increase in film thickness by blowing the Cl gas from the gas supply pads 701 to 711 toward a portion of the wafer W having a thick film thickness. It is also possible to locally increase the film thickness by locally blowing the DCS gas toward a portion of the wafer W having a thin film thickness. With this configuration, the thickness of the film formed on the wafer W can be adjusted with higher accuracy. The gas supply pads 701 to 711 may be provided at positions overlapping with the divided supply portions Z1 to Z11. Even in this case, the similar effects can be obtained as long as the gas supply pads 701 to 711 are provided in end portions of the divided supply portions Z1 to Z11 at the front side rather than the rear side.

### Second Embodiment

Next, a second embodiment in which the supply and cutoff of an Ar gas are switched according to the rotation angle of the rotary table 2 to adjust a deposition amount in the revolution direction of the wafers W will be described.

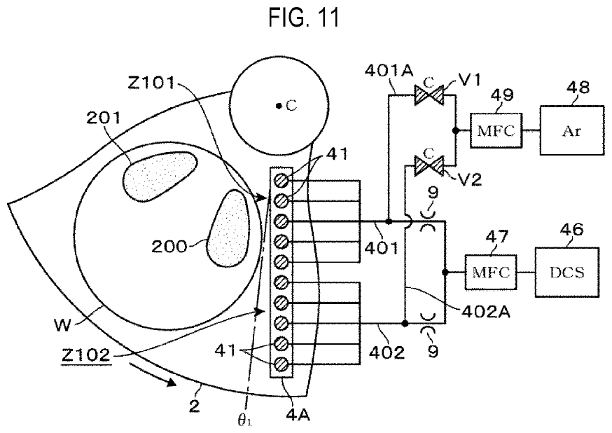

For example, in an example shown in FIG. 11, instead of the gas supply/exhaust unit 4 shown in FIGS. 1 and 2, there is provided a gas supply nozzle 4A, which is a rod-shaped raw material gas supply part having gas discharge holes 41 formed on a lower surface thereof. The gas supply nozzle 4A is disposed above the rotary table 2 so as to traverse the revolution region of the wafers W from the outer peripheral side of the rotary table 2 in the radial direction. The gas supply nozzle 4A is provided to discharge a gas toward the revolution region of the wafers W. In other words, when viewed from the side of the mounting surface of the wafer W, the gas supply nozzle 4A is formed in a rod shape so as to extend in the radial direction from the inner peripheral side to the outer peripheral side of the revolution center of the mounting surface. For example, the gas supply nozzle 4A is divided into two portions in a longitudinal direction to form a divided supply portion Z101 at a distal end side and a divided supply portion Z102 at a proximal end side. A DCS gas is supplied from the gas discharge holes 41 provided in the divided supply portion Z101 toward a gas reception region near the center of the rotary table 2. Furthermore, a DCS gas is supplied from the gas discharge holes 41 provided in the divided supply portion Z102 toward a region of the outer peripheral side of the rotary table 2.

Furthermore, there are provided DCS gas supply lines 401 and 402 by which the divided supply portions Z101 and Z102 are connected to a DCS gas source 46 in a parallel relationship with each other. The aforementioned orifices 9 are provided in the DCS gas supply lines 401 and 402, respectively. Moreover, there are provided Ar gas supply lines 401A and 402A by which the divided supply portions Z101 and Z102 are connected to an Ar gas source 48 in a parallel relationship with each other. Ar gas valves V1 and V2 are provided in the Ar gas supply lines 401A and 402A, respectively.

Furthermore, an encoder is installed in the rotation mechanism 23 of the rotary table 2. The position of the gas supply nozzle 4A and the position of the wafer W can be adjusted by adjusting the rotation angle of the rotary table 2 according to a read value obtained by the encoder. θ₁ to θ₄ shown in FIGS. 11 to 15 described below indicate rotation angles of the rotary table 2 from a predetermined reference position.

Next, the operation of the film forming apparatus according to the second embodiment will be described with reference to FIGS. 11 to 15. For example, when a film formation process is performed without supplying an Ar gas to the divided supply portions Z101 and Z102, it is assumed that thin regions 200 and 201 are respectively formed at the peripheral edges at the upstream side and the downstream side in the rotational direction of the rotary table 2 in portions of the wafer W near the center of the rotary table 2.

For example, first, the film forming process is performed in the same manner as the above-described embodiment while supplying the DCS gas alone from the gas supply nozzle 4A. In this case, as described above, the thin regions 200 and 201 are respectively formed on the wafer W.

Therefore, the film forming apparatus of this example continuously performs film formation so as to compensate for the film thickness in these regions. For example, in a case where the rotation speed of the rotary table 2 in the preceding film forming process is set to 10 rpm, the rotation speed in the current film forming process is reduced to 1 rpm. When the gas supply nozzle 4A is located at the front side of the wafer W (when the gas supply nozzle 4A does not reach the rotation angle θ₁) as shown in FIG. 11, the DCS gas alone is discharged from each of the divided supply portions Z101 and Z102.

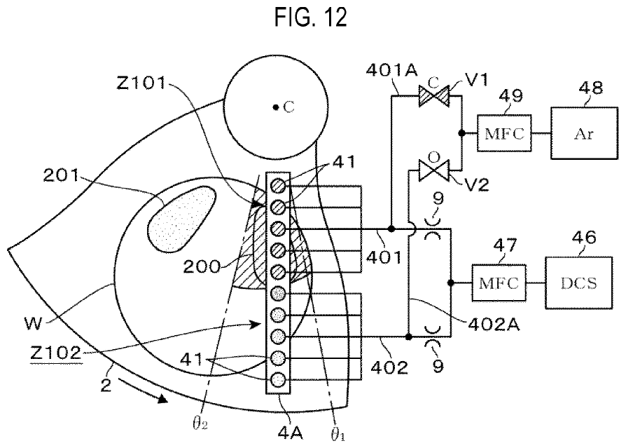

When the rotary table 2 is rotated and the gas supply nozzle 4A is positioned between the rotation angles θ₁ and θ₂ as shown in FIG. 12, the front peripheral edge portion of the wafer W (the aforementioned region 200) is located below the gas supply nozzle 4A. During this period, the supply of the Ar gas is turned off in the divided supply portion Z101 located at the inner peripheral side, and the supply of the Ar gas is turned on in the divided supply portion Z102 located at the outer peripheral side.

As a result, during a period in which the rotation angle of the rotary table 2 falls within a range of θ₁ to θ₂, the DCS gas alone is discharged from the divided supply portion Z101 in the gas supply nozzle 4A toward the inner peripheral side of the rotary table 2. On the other hand, the DCS gas diluted with the Ar gas at the outer peripheral side of the rotary table 2 is supplied from the divided supply portion Z102. With these operations, when the gas supply nozzle 4A is positioned between θ₁ and θ₂, the amount of the DCS gas adsorbed onto the wafer W in the inner peripheral side of the rotary table 2 increases, and the amount of the DCS gas adsorbed onto the wafer W in the outer peripheral side of the rotary table 2 decreases.

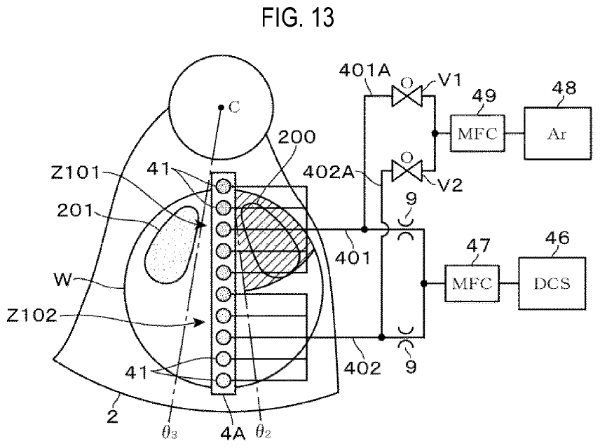

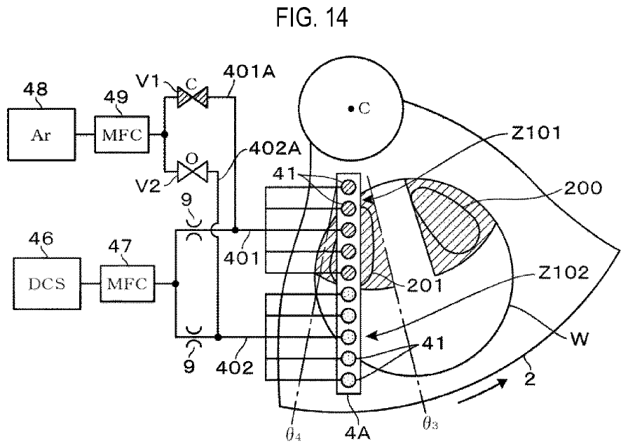

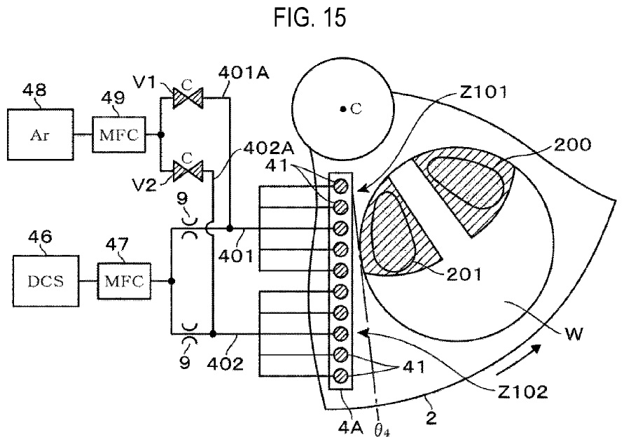

Similarly, during a period from θ2 to θ3 in which the gas supply nozzle 4A is located in the region near the center of the wafer W as shown in FIG. 13, the Ar gas is supplied to both the divided supply portion Z101 located at the inner peripheral side and the divided supply portion Z102 located at the outer peripheral side to dilute the DCS gas. Furthermore, at a position between θ₃ and θ₄ where the rear peripheral edge portion of the wafer W is located below the gas supply nozzle 4A as shown in FIG. 14, the supply of the Ar gas is turned off in the divided supply portion Z101 located at the inner peripheral side, and the supply of the Ar gas is turned on in the divided supply portion Z102 located at the outer peripheral side. Furthermore, as shown in FIG. 15, when the gas supply nozzle 4A is located behind the wafer W, the supply of the Ar gas is turned off in both the divided supply portion Z101 and the divided supply portion Z102 located at the inner and outer peripheral sides.

As described above, the film forming apparatus according to the second embodiment supplies the DCS gas while supplying or cutting off the Ar gas in conformity with the rotation angle of the wafer W. By this operation, the DCS gas not diluted with the Ar gas is supplied to the above-described regions 200 and 201, and the DCS gas diluted with the Ar gas is supplied to other regions. With this configuration, it is possible to adsorb the DCS gas onto the wafer W so as to compensate for a thin portion on the wafer W while suppressing a thick portion from being formed on the wafer W.

It should be noted that the embodiments and modifications disclosed herein are exemplary in all respects and are not restrictive. The above-described embodiments may be omitted, replaced or modified in various forms without departing from the scope and spirit of the appended claims.

### EXAMPLES

In order to verify the effects of the present disclosure, a film forming process was performed by the film forming apparatus using the gas supply/exhaust unit 4 in which some of the divided supply portions ZA to ZE shown in FIG. 8 are arranged in an island shape. The variation in film thickness with respect to the supply flow rate of the Ar gas during the film forming process was investigated.

In both Example 1 and Example 2, two divided supply portions ZD and ZE among the five divided supply portions ZA to ZE were configured to have in an island shape and were arranged at the inner peripheral side and the outer peripheral side of the rotary table 2, respectively.

### Example 1

The two island-shaped divided supply portions ZD and ZE were provided so as to discharge gases over a range of an angle of 5 degrees while coinciding with the rotation center C of the rotary table 2.

### Example 2

The two island-shaped divided supply portions ZD and ZE were provided so as to discharge gases over a range of an angle of 14 degrees while coinciding with the rotation center C of the rotary table 2.

Film forming processes were performed using the film forming apparatus provided with each of the gas supply/exhaust units 4 of Example 1 and Example 2. The film thickness distribution when the Ar gas is supplied to each of the island-shaped divided supply portions ZD and ZE to form a film on the wafer W was investigated.

The flow rates of the DCS gas, the NH₃ gas and the H₂ gas were set in the same manner as in the above embodiments, the rotational speed of the rotary table 2 was set to 10 rpm, and the film forming process was performed for 15 minutes. At that time, the film forming process was performed by supplying the DCS gas while supplying the Ar gas in each of the island-shaped divided supply portions ZD and ZE. The flow rate of the Ar gas was set to 0, 3, 6, 12, 20, 50 and 75 sccm by the MFC 49 provided in the Ar gas supply pipe 440. The film forming process was performed at each flow rate of the Ar gas.

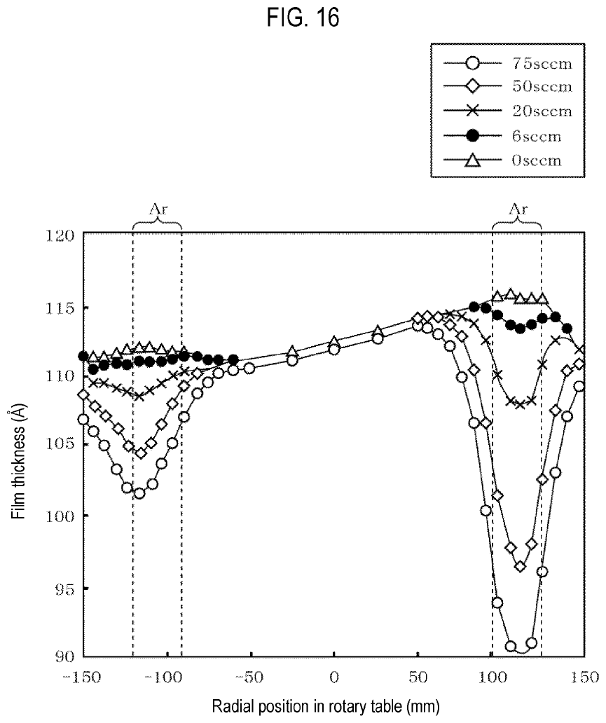

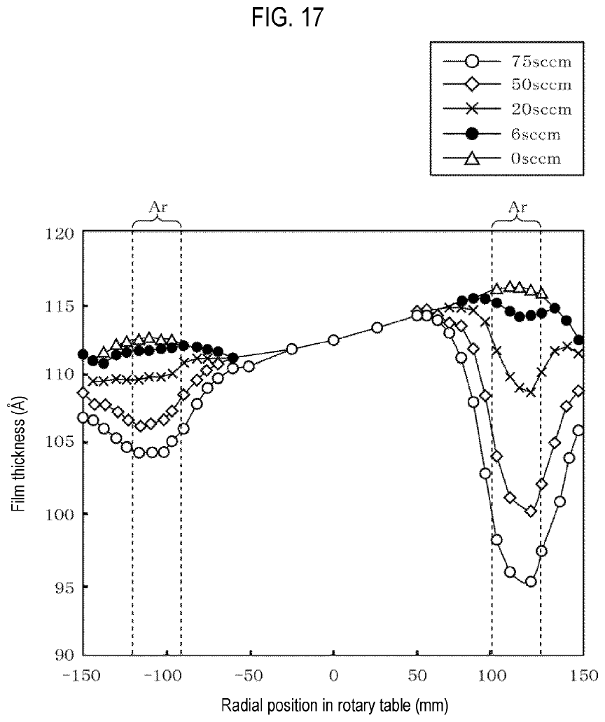

FIGS. 16 and 17 show the results of measurement of the film thickness distribution in the radial direction of the rotary table 2 for each flow rate of the Ar gas in Examples 1 and 2, respectively. In the horizontal axis of FIGS. 16 and 17, 0 indicates the center of the wafer W, the position of +150 mm indicates the peripheral edge of the wafer W positioned at the inner peripheral side of the rotary table 2, and the position of −150 mm indicates the peripheral edge of the wafer W positioned at the outer peripheral side of the rotary table 2. Furthermore, as indicated in the upper portion of the graph, the positions (the regions corresponding to the island-shaped divided supply portions ZD and ZE) at which the Ar gas is supplied are positions ranging from −90 mm to −120 mm and ranging from +90 mm to 120 mm. In FIGS. 16 and 17, the results obtained when the flow rate of the Ar gas is set to 3 and 12 sccm are omitted for the sake of avoiding complexity of the graph.

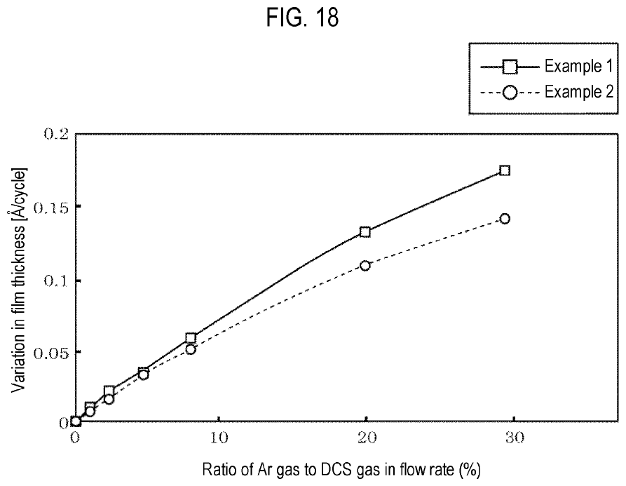

FIG. 18 shows the variation in thickness of the film formed on the wafer W passing through the gas reception regions facing the divided supply portions ZD and ZE when the flow rate of the Ar gas supplied to each of the divided supply portions ZD and ZE in Example 1 and Example 2 is set to each flow rate. The vertical axis in FIG. 18 indicates the variation in film thickness, and the horizontal axis indicates the flow rate of the Ar gas (the set value of the MFC 49) relative to the flow rate of the DCS gas (the set value of the MFC 47). The variation in film thickness refers to a difference value obtained by subtracting the in-plane average value of the thicknesses of the films formed when the flow rate of the Ar gas is set to each flow rate from the in-plane average value of the thicknesses of the films formed when the flow rate of the Ar gas is set to 0. The variation in film thickness indicates a variation in film thickness per cycle (one rotation of the rotary table 2) of the supply of the DCS gas and the NH₃ gas.

As shown in FIGS. 16 and 17, it can be said that the film thickness of the formed film can be reduced by supplying the Ar gas to the island-shaped divided supply portions ZD and ZE and diluting the DCS gas with the Ar gas. It can also be said that the amount of decrease in film thickness can be increased by increasing the flow rate of the Ar gas. Furthermore, as shown in FIG. 18, Example 1 shows a larger variation in film thickness than that of Example 2 when the flow rate of the Ar gas is the same. Accordingly, in the configuration in which the film thickness is adjusted by discharging the Ar gas, the variation in film thickness with respect to the variation in flow rate of the Ar gas can be adjusted by adjusting a length of the divided supply portions ZD and ZE in the revolution direction of the wafers W. Furthermore, it can be said that the variation in film thickness with respect to the supply time of the Ar gas can be increased by increasing the length of the divided supply portions ZD and ZE in the revolution direction of the wafers W.

According to the present disclosure in some embodiments, it is possible to adjust a film thickness distribution in a plane of a substrate when forming a film by supplying gases to the substrate.

What is claimed is:

1. A film forming apparatus for forming a thin film by alternately supplying a raw material gas and a reaction gas to a substrate in a repetitive manner, comprising:
a stage on which the substrate is mounted;
a raw material gas supply part configured to supply the raw material gas to the substrate mounted on the stage and adsorb the raw material gas onto the substrate, the raw material gas supply part including a plurality of divided supply portions configured to independently supply the raw material gas toward a plurality of gas reception regions which are set by dividing a mounting surface of the stage on which the substrate is mounted;
a plurality of raw material gas supply lines by which the plurality of divided supply portions are connected to a raw material gas source, the plurality of raw material gas supply lines configured to supply the raw material gas toward the raw material gas supply part in a parallel relationship with each other;
a plurality of concentration adjustment gas supply lines by which the plurality of divided supply portions are connected to a concentration adjustment gas source, the plurality of concentration adjustment gas supply lines configured to supply a concentration adjustment gas for adjusting a concentration of the raw material gas toward the raw material gas supply part in a parallel relationship with each other, each of the plurality of concentration adjustment gas supply lines including supply/cutoff valves for selecting some of the plurality of divided supply portions to supply the concentration adjustment gas; and
a reaction gas supply part configured to supply the reaction gas reacting with the raw material gas adsorbed onto the substrate to generate a reaction product constituting the thin film.

2. The apparatus of claim 1, wherein each of the raw material gas supply lines includes a flow rate ratio adjustment part configured to sort the raw material gas supplied from the raw material gas source at a predetermined flow rate ratio.

3. The apparatus of claim 2, wherein the stage is configured to revolve along the mounting surface,
wherein the plurality of divided supply portions are divided in a radial direction from an inner peripheral side toward an outer peripheral side of a revolution center of the mounting surface, and
wherein the raw material gas supply part and the reaction gas supply part are arranged apart from each other in the revolution direction.

4. The apparatus of claim 3, wherein the raw material gas supply part is formed in a fan shape so as to extend from the inner peripheral side toward the outer peripheral side of the revolution center when viewed from a side of the mounting surface.

5. The apparatus of claim 4, wherein the plurality of divided supply portions includes an island-shaped divided supply portion provided between two divided supply portions arranged at positions adjacent to each other along the radial direction.

6. The apparatus of claim 5, further comprising: a plurality of reaction inhibition gas supply parts configured to adjust a film thickness of the thin film by causing a reaction inhibition gas, which does not generate the reaction product even when the reaction gas is supplied, to be adsorbed onto the substrate, the plurality of reaction inhibition gas supply parts being provided at different positions in the radial direction in a region just before the substrate mounted on the stage enters a position at which the raw material gas supplied from the raw material gas supply part is supplied to the substrate with the revolution of the stage.

7. The apparatus of claim 6, further comprising: a raw material gas preliminary supply part provided in the region, instead of some of the plurality of reaction inhibition gas supply parts, and configured to supply the raw material gas.

8. The apparatus of claim 3, wherein the raw material gas supply part is formed in a rod shape so as to extend in the radial direction from the inner peripheral side to the outer peripheral side of the revolution center when viewed from a side of the mounting surface.

9. The apparatus of claim 3, further comprising: a plurality of reaction inhibition gas supply parts configured to adjust a film thickness of the thin film by causing a reaction inhibition gas, which does not generate the reaction product even when the reaction gas is supplied, to be adsorbed onto the substrate, the plurality of reaction inhibition gas supply parts being provided at different positions in the radial direction in a region just before the substrate mounted on the stage enters a position at which the raw material gas supplied from the raw material gas supply part is supplied to the substrate with the revolution of the stage.

10. The apparatus of claim 1, wherein the stage is configured to revolve along the mounting surface,
wherein the plurality of divided supply portions are divided in a radial direction from an inner peripheral side toward an outer peripheral side of a revolution center of the mounting surface, and
wherein the raw material gas supply part and the reaction gas supply part are arranged apart from each other in the revolution direction.

11. A method of forming a thin film by alternately supplying a raw material gas and a reaction gas toward a substrate in a repetitive manner, the method comprising:
mounting the substrate on a stage;
supplying the raw material gas to the substrate mounted on the stage and adsorbing the raw material gas onto the substrate using a raw material gas supply part, the raw material gas supply part including a plurality of divided supply portions configured to independently supply the raw material gas toward a plurality of gas reception regions which are set by dividing a mounting surface of the stage on which the substrate is mounted; and
supplying the reaction gas which reacts with the raw material gas adsorbed onto the substrate to generate a reaction product constituting the thin film,
wherein the raw material gas supplied to the substrate is sorted at a predetermined flow rate ratio through a plurality of raw material gas supply lines, the plurality of divided supply portions being connected to a raw material gas source configured to supply the raw material gas toward the raw material gas supply part in a parallel relationship with each other by the plurality of raw material gas supply lines; and
wherein a concentration of the raw material gas is adjusted by a concentration adjustment gas supplied from some of the divided supply portions selected out of the plurality of divided supply portions via a plurality of concentration adjustment gas supply lines including supply/cutoff valves, the plurality of divided supply portions being connected to a concentration adjustment gas source configured to supply the concentration adjustment gas for adjusting the concentration of the raw material gas toward the raw material gas supply part in a parallel relationship with each other through the plurality of concentration adjustment gas supply lines.

12. The method of claim 11, wherein the stage is configured to revolve along the mounting surface,
wherein the plurality of divided supply portions are divided in a radial direction from an inner peripheral side to an outer peripheral side of a revolution center of the mounting surface, and
wherein the raw material gas and the reaction gas are supplied to positions spaced apart from each other in the revolution direction.

13. The method of claim 12, further comprising: adjusting a film thickness of the thin film by causing a reaction inhibition gas, which does not generate the reaction product even when the reaction gas is supplied, to be adsorbed onto the substrate, using a plurality of reaction inhibition gas supply parts, the plurality of reaction inhibition gas supply parts being provided at different positions in the radial direction in a region just before the substrate mounted on the stage enters a position at which the raw material gas supplied from the raw material gas supply part is supplied to the substrate with the revolution of the stage.
